(19) United States
(12) Patent Application Publication
(10) Pub. No.: US 2023/0275044 A1
(43) Pub. Date: Aug. 31, 2023

(54) ELECTRONIC COMPONENT PACKAGE WITH INTEGRATED COMPONENT AND REDISTRIBUTION LAYER STACK

(71) Applicant: Smoltek AB, GÖTEBORG (SE)

(72) Inventor: Karl Lundahl, GÖTEBORG (SE)

(21) Appl. No.: 18/040,170

(22) PCT Filed: Sep. 7, 2021
(86) PCT No.: PCT/SE2021/050853

§ 371 Date: Feb. 1, 2023

(30) Foreign Application Priority Data
Sep. 10, 2020 (SE) 2051064-0

(51) Int. Cl. H01L 23/64; H01L 23/498; H01L 23/00; H01L 21/48; H01L 25/16

(52) U.S. Cl. CPC H01L 23/642; H01L 23/49822; H01L 23/49833; H01L 23/49838; H01L 23/49816; H01L 24/08; H01L 21/4853; H01L 21/4857; H01L 21/486; H01L 25/16; H01L 28/75; H01L 28/90; H01L 2224/08265; H01L 2924/1205

(57) ABSTRACT

An electronic component package, comprising a package part comprising a plurality of contact pads on a first surface of the package part; a passive component having a first surface including contact pads bonded to a first set of contact pads in the plurality of contact pads and a second surface spaced apart from the first surface; a plurality of connecting structures for external electrical connection of the electronic component package; and an RDL stack interconnecting a second set of contact pads in the plurality of contact pads with the connecting structures for external electrical connection, the RDL stack comprising: a first conductor layer; a second conductor layer; and a dielectric layer arranged there between and comprising vias for conductively connecting the first conductor layer and the second conductor layer.

### FIELD OF THE INVENTION

The present invention relates to an electronic component package and to a method of manufacturing an electronic component package.

### BACKGROUND OF THE INVENTION

Miniaturization of electronics has been the trend for many decades, which has enabled us to witness different kinds of gadgets with many functionalities. To a large part, this progress was enabled by miniaturizing and integrating transistors, resistors and capacitors for logic applications onto silicon. By comparison, passive components (resistors, capacitors, and inductors) at the circuit-board level have made only incremental advances in size and density. As a consequence, passive components occupy an increasingly larger area and mass fraction of electronic systems and are a major hurdle for further miniaturization of many electronic systems with lower system cost. For example, current smartphones typically use more than 1000 discrete passive components. A circuit board of an electric car utilizes roughly 10000 such discrete passive components and the trend is upwards. The need for such a large numbers of passive components, is primarily driven by the need to tackle the problem with power management systems driving the power all the way from the source of energy (battery/mains power) through the packaging schemes (PCB/SLP/SiP) to the chip integrated circuits.

Miniaturization of silicon circuits allows more functions per unit area. Such achievements have come with a price and have stressed the power management system of the die to the extreme. Today's silicon chips suffer heavily from power noise induced by leakage current from the transistors, high frequency reflections in the interconnect grids, parasitics switching noise etc. along the power grid. Such power noise can cause voltage fluctuation and impedance mismatch of the circuit and may result in gate delay and logic errors, jitter, etc. and can be catastrophic. One of the ways to tackle such problem is to use passive circuitry, including metal insulator metal (MIM) decoupling capacitors integrated in the IC. However, such integrated schemes to tackle the problems inside of a die is limited by white space (expensive real estate space available on die) to integrate passive circuitry, such as decoupling capacitors on the surface of the die. It is reported that the white space is decreasing and that only about 10% is allocated in today's generation per die, for on chip decoupling capacitors.

Recently, more compact passive components, such as the discrete MIM energy storage components described in WO 2020/080993 have been developed. Such compact passive components may be integrated in electronic component packages, for instance on the backside of an electronic component package, between the connecting structures (such as solder balls) of the electronic component package.

Although such an arrangement of novel compact passive components, or indeed any components, represents a huge step forward compared to arranging passive components between electronic component packages on the circuit board, improvement areas still exist. For instance, arranging components between connecting structures on the backside of an electronic component package may limit the connecting structure density of the electronic component package, so that the electronic component package occupies more circuit board space than should be necessary.

It would therefore be desirable to provide an improved electronic component package with at least one integrated component, in particular such an electronic component package allowing an increased connecting structure density.

### SUMMARY

It is an object of the present invention to provide an improved electronic component package with at least one integrated component, in particular such an electronic component package allowing an increased connecting structure density.

According to a first aspect of the present invention, it is therefore provided an electronic component package, comprising: a package part comprising a plurality of contact pads on a first surface of the package part; a component having a first surface including contact pads bonded to a first set of contact pads in the plurality of contact pads on the first surface of the package part, and a second surface spaced apart from the first surface; a plurality of connecting structures for external electrical connection of the electronic component package; and an RDL stack interconnecting a second set of contact pads in the plurality of contact pads on the first surface of the package part with the connecting structures for external electrical connection, the RDL stack comprising: a first conductor layer arranged between the first surface of the package part and a plane including the second surface of the component; a second conductor layer arranged between the first conductor layer and the plane including the second surface of the component; and a dielectric layer arranged between the first conductor layer and the second conductor layer and comprising vias for conductively connecting the first conductor layer and the second conductor layer.

It should be understood that the first and second surfaces of the component may be substantially parallel to each other, and to the top surface of the package part. Accordingly, the above-mentioned plane including the second surface of the component may be substantially parallel to the top surface of the package part.

Through the RDL-stack configuration specified above, the first and second conductor layers of the RDL stack thus surround a side surface of the component. The RDL stack may have additional conductor layers which may or may not surround the side surface of the component.

The present invention is based on the realization that an electronic component package with the added functionality provided by the integration of at least one component can be achieved without decreasing the connecting structure density of the electronic component package, by embedding the at least one component in an RDL stack interconnecting a package part, such as an integrated circuit or an interposer, with the connecting structures of the electronic component package.

The component may, in principle, be any component, including a passive component, an active component, and a component fulfilling another function, such as a thermal component. An example of a thermal component may be a heat sink. It should be noted that the term “passive component” should be understood to encompass a passive component with a single electrical circuit functionality, such as a capacitor, a resistor or an inductor, as well as a passive component with combined electrical circuit functionality, such as a combine capacitor and inductor, etc. The latter kind of passive component may be referred to as an integrated passive device (IPD).

According to embodiments, the RDL stack may fully embed the component, including the second surface of the component.

By fully embedding the component by the RDL stack (including the side surface and the second surface of the component), connecting structures can be arranged wherever deemed suitable, without considering the component. In particular, this can be achieved without forming vias (such as so-called through-silicon vias, TSVs) through the component, which would add cost and complexity to the electronic component package.

In various embodiments, the RDL stack may further comprise a third conductor layer at least partly covering the second surface of the component.

Furthermore, the component may be at least partly covered by at least one connecting structure in the plurality of connecting structures for external electrical connection of the electronic component package. The number of connecting structures covering the component may depend on the size of the component, as well as the desired density of connecting structures of the electronic component package. In embodiments, a component may be covered by at least four or more connecting structures, that are connected to contact pads of the package part via the RDL stack.

According to various embodiments, the electronic component package may include a capacitor component, which may, for example, be beneficial for designing the power distribution network (PDN) of an electronic system including the electronic component package. Through the embedded arrangement of one or more capacitor component(s), the inductance can be reduced, and a more compact electronic system may be provided for.

In embodiments, furthermore, the capacitor component may be a discrete nano-structure based capacitor, comprising: at least a first plurality of electrically conductive nanostructures; a dielectric material embedding each nanostructure in the first plurality of conductive nanostructures; a first electrode conductively connected to each nanostructure in the first plurality of nanostructures; a second electrode separated from each nanostructure in the first plurality of nanostructures by the dielectric material, wherein: a first contact pad on the first surface of the capacitor component is conductively connected to the first electrode; and a second contact pad on the first surface of the capacitor component is conductively connected to the second electrode.

Since nano-structure based capacitors can be made extremely thin, such as less than 100 μm, less than 50 μm, or even less than 20 μm, in combination with a relatively high capacitance, such capacitors are extremely suitable for being embedded in an RDL stack.

According to various embodiments, the conductive nanostructures in the first plurality of conductive nanostructures may be vertical nanostructures grown from the first electrode, which may be a first electrode layer. The use of grown nanostructures allows extensive tailoring of the properties of the nanostructures. For instance, the growth conditions may be selected to achieve a morphology giving a large surface area of each nano-structure, which may in turn increase the energy storage capacity of the nano-structure energy storage device.

The nanostructures may be selected from one of nanowire, nano-horns, nanotube, nano-walls, crystalline nanostructures, or amorphous nanostructures.

The nanostructures may advantageously be carbon nanostructures, such as carbon nanofibers, carbon nanotubes or carbide-derived carbon nanostructures.

According to embodiments, the dielectric material may advantageously be arranged as a conformal coating on each nanostructure in the first plurality of conductive nanostructures.

According to embodiments, the second electrode may cover the dielectric material.

The dielectric material in the nano-structure based capacitor(s) provides for energy storage by preventing electrical conduction from the conductive nanostructures in the first plurality of nanostructures to the second electrode. Hereby, energy can be stored through accumulation of charge at the nanostructure—dielectric interface. The dielectric may advantageously be a so-called high-k dielectric. The high k-dielectric materials e.g. be HfOx, HfAlOx, TiOx, TaOx, NiOx, MoOx, CuOx, PZT, BaTiOx, or other well-known high k dielectrics. Alternatively, the dielectric can be polymer based e.g. polypropylene, polystyrene, poly(p-xylylene), parylene, PBO etc. Other well-known dielectric materials, such as SiOx or SiNx, etc may also be used. The dielectric material or materials may be deposited via CVD, thermal processes, ALD or spin coating or spray coating or any other suitable method used in the industry.

According to a second aspect of the present invention, there is provided a method of manufacturing an electronic component package, comprising the steps of: providing a package part having a first surface including a plurality of contact pads; providing a component having a first surface including contact pads, a second surface substantially parallel to the first surface and spaced apart from the first surface, and a side surface connecting the first surface and the second surface; bonding the contact pads on the first surface of the component to a first set of contact pads in the plurality of contact pads on the first surface of the package part; forming, on a portion of the first surface of the package part and on the second surface of the component, an RDL stack embedding the component, the RDL stack comprising at least a bottom conductor pattern bonded to a second set of contact pads in the plurality of contact pads on the first surface of the package part, a top conductor pattern defining a plurality of connecting structures for external connection of the electronic component package, and at least one dielectric layer arranged between the bottom conductor pattern and the top conductor pattern and comprising vias for conductively connecting the bottom conductor pattern with the top conducting pattern.

In summary, the present invention thus relates to an electronic component package, comprising a package part comprising a plurality of contact pads on a first surface of the package part; a component having a first surface including contact pads bonded to a first set of contact pads in the plurality of contact pads on the first surface of the package part, and a second surface spaced apart from the first surface; a plurality of connecting structures for external electrical connection of the electronic component package; and an RDL stack interconnecting a second set of contact pads in the plurality of contact pads on the first surface of the package part with the connecting structures for external electrical connection, the RDL stack comprising: a first conductor layer; a second conductor layer; and a dielectric layer arranged between the first conductor layer and the second conductor layer and comprising vias for conductively connecting the first conductor layer and the second conductor layer.

### BRIEF DESCRIPTION OF THE DRAWINGS

These and other aspects of the present invention will now be described in more detail, with reference to the appended drawings showing example embodiments of the invention, wherein:

FIG. 1 schematically shows an example electronic device, here in the form of a mobile phone, including an electronic system according to embodiments of the present invention;

FIG. 2 is an enlarged view of a portion of the electronic system in FIG. 1;

FIG. 3 is an example illustration of an electronic component package according to the prior art;

FIG. 4 schematically shows an example embodiment of an electronic component package according to the present invention;

FIG. 5A is a schematic partial cross-section view of the electronic component package in FIG. 4;

FIG. 5B is an enlarged view of a part of the illustration in FIG. 5A;

FIG. 6A is a partly opened perspective schematic illustration of an exemplary passive component, in the form of a MIM energy storage component, comprised in the electronic component package in FIGS. 5A-B;

FIG. 6B is a schematic cross-section view of the MIM energy storage component in FIG. 6A;

FIG. 7 is an enlarged illustration of an example configuration of the MIM energy storage component in FIGS. 6A-B; and

FIG. 8 is a flow-chart illustrating an example embodiment of a method according to embodiments of the present invention.

### DETAILED DESCRIPTION OF EXAMPLE EMBODIMENTS

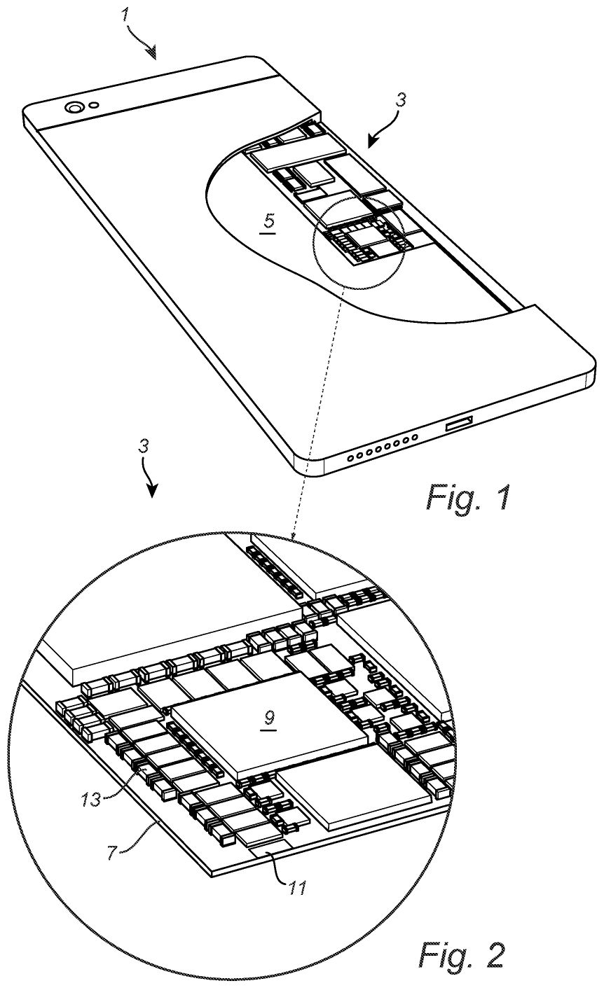

FIG. 1 schematically illustrates an electronic device according to embodiments of the present invention, here in the form of a mobile phone 1. In the simplified and schematic illustration in FIG. 1, it is indicated that the mobile phone, like most electronic devices, comprises an electronic system 3 controlling operation of the electronic device 1, and a power source, here in the form of a battery 5, for supplying power to the electronic system 3 and other parts of the electronic device 1.

Although the electronic device according to embodiments of the present invention has here been exemplified by a mobile phone 1, it should be understood that the electronic component package according to various embodiments of the present invention may equally well be included in, and useful for, other types of electronic devices, such as, for example: an AR, VR, MR; an entertainment unit; a navigation device; a communications device; a fixed location data unit; a mobile location data unit; a global positioning system (GPS) device; a smart watch; a wearable computing device; a tablet; a server; a computer; a portable computer; a mobile computing device; a battery charger; a USB device; a desktop computer; a personal digital assistant (PDA); a monitor; a computer monitor; a television; a tuner; a radio; a satellite radio; a music player; a digital music player; a portable music player; a digital video player; an automobile; an electric vehicle; a vehicle component; avionics systems; a drone; and a multicopter.

In modern electronic devices, the electronic system 3 (in some applications also referred to as logic board) needs to be able to handle very heavy computational tasks, which may, for example, include advanced image processing etc. The electronic system 3 may also need to intermittently handle various diverse tasks simultaneously. Such tasks may involve processing carried out by different semiconductor components, that may be at least partly specialized for carrying out their respective tasks.

FIG. 2 is an enlarged view of the electronic system 3 in FIG. 1, and schematically shows that the electronic system 3 comprises a substrate 7, a plurality of semiconductor components 9 (only one of the semiconductor components in FIG. 2 is indicated by a reference numeral, in order to avoid cluttering the drawing), and a power source interface 11 for receiving power from the power source 5. In order to efficiently and reliably distribute power from the power source interface 11 to the semiconductor components 9, the electronic system 3 further comprises a power distribution network (PDN). As is discussed and explained further above, there may be severe requirements on the PDN. The PDN should be capable of supplying sufficient power, at well-defined voltage levels, to all of the semiconductor components 9 of the electronic system 3 across a broad frequency range. For example, different semiconductor components 9 may exhibit sudden variations in the required power. The PDN should be capable of accommodating this without excessive variations in the supply voltage and without disturbing the supply of power to other semiconductor components. Designing and dimensioning the PDN is therefore a challenging task facing the team developing the electronic system 3. A successful PDN may require careful design of the substrate 7, the semiconductor components 9, as well as purposeful selection and arrangement of a large number of capacitor components 13 (again, only one of the capacitors included in the PDN is indicated by a reference numeral in FIG. 2).

Embodiments of the present invention enable the design of PDNs in electronic systems with less substrate space occupied by components, such as capacitors and may also provide for a reduction in the footprint of electronic components 9. This in turn provides for more compact electronic systems, which may allow for electronic devices with smaller dimensions and/or improved performance. For example, a larger battery may be accommodated for given overall dimensions of an electronic device such as a mobile phone 1. Smaller physical dimensions of an electronic system may in itself contribute to facilitating the design and configuration of the PDN for the electronic system, due to the reduced inductances resulting from shorter conductor lengths.

Moreover, the disclosed subject matter provides novel means for a circuit designer to meet power integrity guidelines set by end users, such as manufacturers of a given device (e.g., a mobile phone, computer etc.).

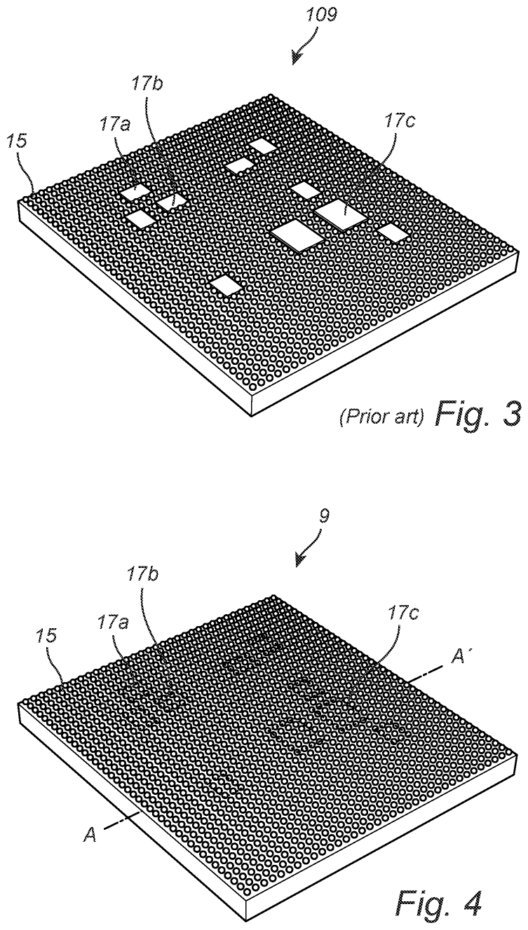

FIG. 3 schematically shows the mounting side of an electronic component package 109 according to the state of the art. The electronic component package 109 comprises a large number of connecting structures 15, in this case BGA solder balls, for externa electrical connection of the electronic component package 109. As is shown in FIG. 3, the electronic component package 109 is provided with passive components 17a-c arranged among the connecting structures 15. With this state of the art configuration, the passive components 17a-c can be arranged in close proximity to integrated circuits, which may simplify the design and realization of the PDN-system as described above.

With the state of the art configuration in FIG. 3, however, the area of the component package 109 is increased, since the area occupied by the passive components 17a-c cannot be populated by connecting structures 15.

FIG. 4 is a schematic illustration of an electronic component package 9 according to embodiments of the present invention, in which the passive components 17a-c are integrated in the electronic component package 9 in such a way that the connecting structures 15 can be distributed across the entire mounting side of the electronic component package 9. This provides for a reduction in the area of the electronic component package 9, which has various advantages as described above.

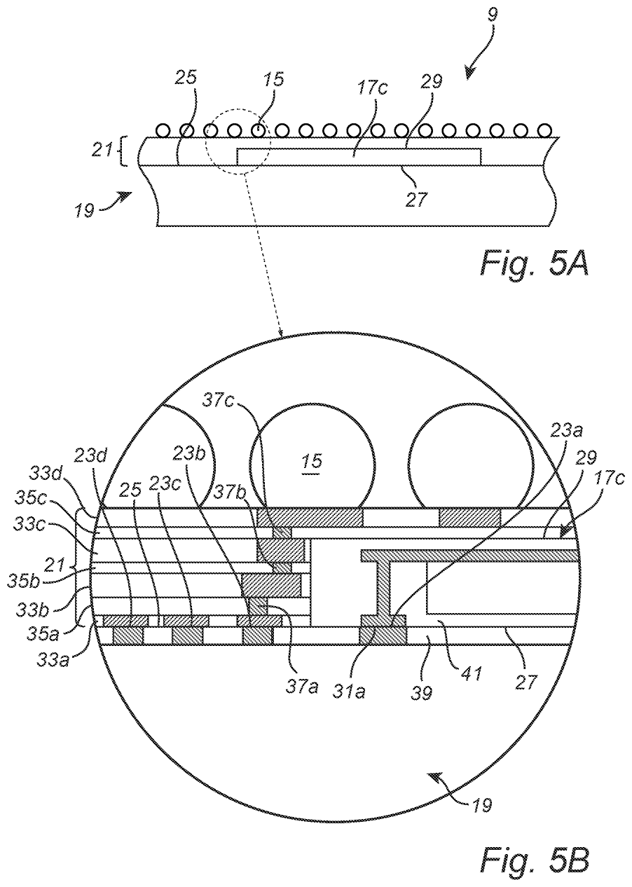

FIG. 5A is a schematic partial cross-section view of the electronic component package 9 in FIG. 4, of the cross-section taken along the line A-A′ in FIG. 4. FIG. 5B is an enlarged view of a part of the illustration in FIG. 5A.

Referring to FIGS. 5A-B, the electronic component package 9 comprises, in addition to the above-mentioned connecting structures 15 and components, such as passive components 17a-c (only one of the passive components 17c is in the cross-section view in FIGS. 5A-B), a package part 19, and an RDL stack 21.

As can be seen in FIG. 5B, the package part 19 comprises contact pads 23a-d on a first surface 25 of the package part 19. The passive component 17c that is visible in FIGS. 5A-B has (referring mainly to FIG. 5B) a first surface 27 and a second surface 29 spaced apart from the first surface 27. The first surface 27 of the passive component 17c includes contact pads 31a-b (only one 31a of these is visible in FIG. 5B) bonded to a first set 23a of the contact pads on the first surface 25 of the component part 19.

In the example configuration of the electronic component package 9 in FIGS. 5A-B, the RDL-stack 21 comprises a first conductor layer 33a, a second conductor layer 33b, a third conductor layer 33c, and a fourth conductor layer 33d. As is schematically indicated in FIG. 5B, the RDL-stack 21 further includes a first dielectric layer 35a between the first 33a and second 33b conductor layers, a second dielectric layer 35b between the second 33b and third 33c conductor layers, and a third dielectric layer 35c between the third 33c and fourth 33d conductor layers. The dielectric layers 35a-c comprises vias 37a-c for conductively connecting the pairs of conductor layers that are separated by the respective dielectric layers.

The RDL stack 21 embeds the passive component 17c, and interconnects a second set 23b-d of the contact pads on the first surface 25 of the package part 19 with the connecting structures 15 for external electrical connection. In the cross-section view of FIG. 5B, the interconnection between one contact pad 23b and one of the connecting structures 15 is visible. This interconnection may be realized by the conductor layers 33a-33d and the vias 37a-c as is schematically shown in FIG. 5B.

With continued reference to FIG. 5B, the first 33a, the second 33b, and the third 33c conductor layers are all arranged between the first surface 25 of the package part 9 and a plane including the second surface 29 of the passive component 17c. The fourth conductor layer 33d completely covers the passive component 17c and provides connection points of connecting structures 15 covering the passive component 17c.

For compact and reliable connection, the passive component 17c may be bonded to the package part 19 by covalent bonds. To that end, referring to FIG. 5B, each contact pad 23a in the first set of the plurality of contact pads on the first surface 25 of the package part 19 may be surrounded by an oxide layer 39, and each contact pad 31a on the first surface 27 of the passive component 17c may be surrounded by an oxide layer 41. The oxide layer 39 on the first surface 25 of the package part 19 and the oxide layer 41 on the first surface 27 of the package component 17c may be bonded to each other by covalent bonds. The contact pads 23a of the package part 19 and the corresponding contacts pads 31 of the passive component 17c may also be bonded to each other by covalent bonds.

According to one exemplary method of forming such covalent bonds, an initial oxide to oxide bond may be formed at room temperature, and then the metal to metal bond may be formed by heating, whereby the different CTEs of the oxide and the metal result in metal to metal pressure, enabling the formation of covalent metal to metal bonds.

The package part 19 may, for example, include a semiconductor circuit, such as an integrated circuit, which may be a processor circuit. In embodiments, the first surface 25 of the package part 19 may be constituted by a first surface of the semiconductor circuit. In embodiments, furthermore, the package part 19 may include an interposer. In such embodiments, the first surface 25 of the package part 19 may be constituted by a first surface of the interposer. In the latter embodiments, a semiconductor circuit may be mounted on the first surface of the interposer, or on a second surface of the interposer, opposite to the first surface.

According to various embodiments, the passive component 17c may be an energy storage component, such as a capacitor component.

Advantageously such an energy storage component may be nanostructure-based, since such a component may provide for a beneficial combination of a high energy storage capability and a very low profile, such as less than 50 μm, or even less than 20 μm.

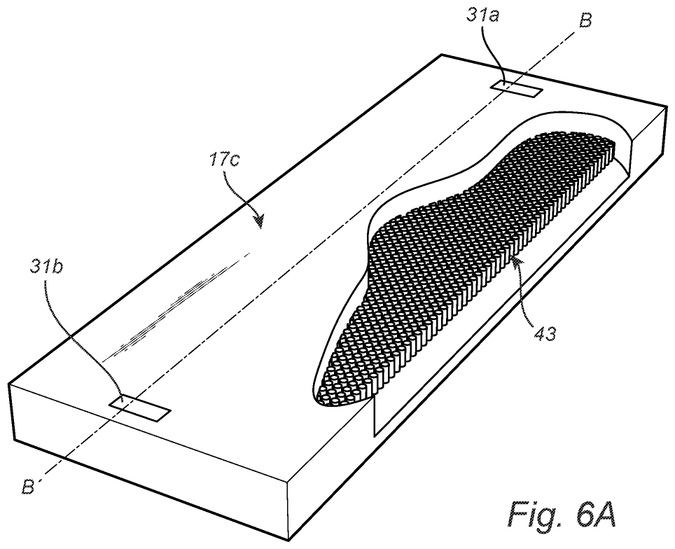

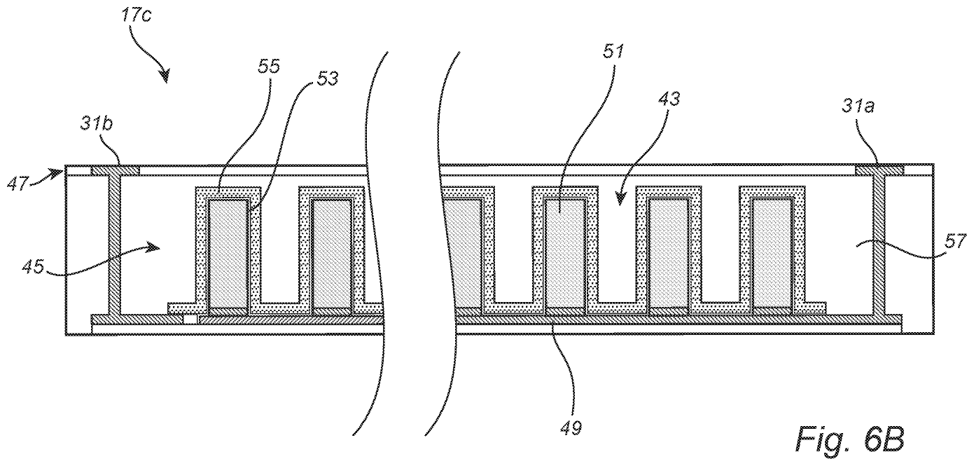

FIG. 6A is a partly opened perspective schematic illustration of an exemplary passive component, in the form of a MIM energy storage component 17c, that may be comprised in the electronic component package 9 in FIGS. 5A-B. The MIM energy storage component 17c may be a discrete capacitor component, comprising a MIM-arrangement 43, a first contact pad 31a, a second contact pad 31b, and a dielectric encapsulation material, at least partly embedding the MIM-arrangement 43 to at least partly form an outer boundary surface of the energy storage component 17c.

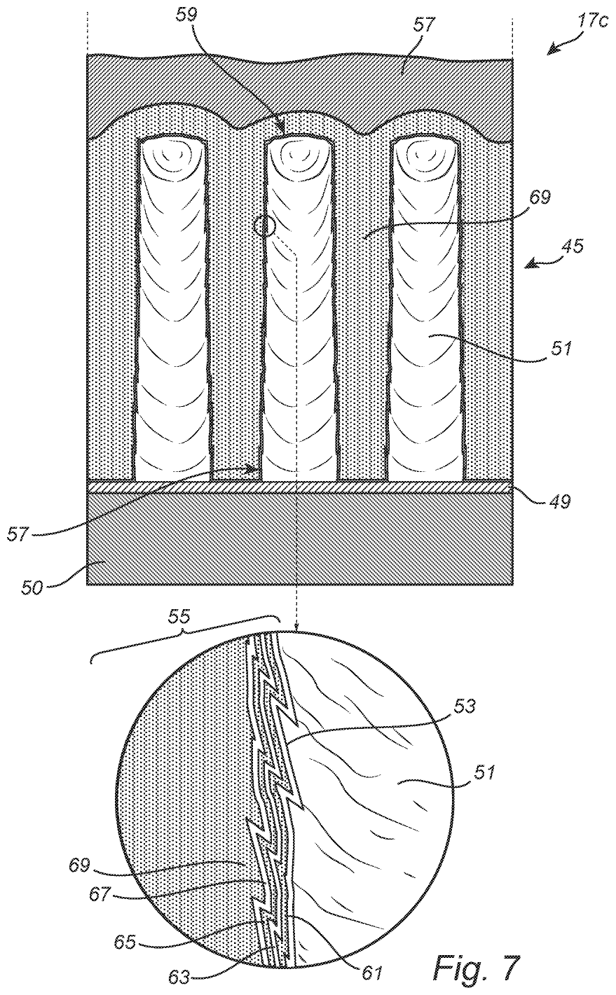

FIG. 6B is a schematic cross-section view of the MIM energy storage component 17c in FIG. 6A, of the section taken along the line B-B′ in FIG. 6A. In FIG. 6B, it can be seen that this embodiment of the MIM energy storage component comprises a MIM energy storage component layer 45 and a contact pad layer 47. The MIM energy storage component layer 45 comprises a bottom electrode 49, a plurality of electrically conductive vertical nanostructures 51 (only one of these is indicated by a reference numeral in FIG. 6B to avoid cluttering the drawings), a bottom conduction-controlling layer 53, and a layered stack 55 comprising alternating conduction-controlling layers and electrode layers conformally coating the bottom conduction-controlling layer 53. An example configuration of the MIM energy storage component layer 45 will be described in greater detail below, with reference to FIG. 7.

The contact pad layer 47 comprises the first contact pad 31a and the second contact pad 31b referred to above with reference to FIG. 6A and the oxide layer 41 described above in connection with FIG. 5B. As is schematically indicated in FIG. 6B, the first contact pad 31a is electrically conductively connected to the bottom electrode 49, and the second contact pad 31b is electrically conductively connected to selected electrode layers in the layered stack 55. In particular, the second contact pad 31b is electrically conductively connected to each odd-numbered electrode layer in the layered stack 55. This will become clearer below, when the configuration of the layered stack 55 is explained in greater detail with reference to FIG. 7. It should also be noted that, although it may be beneficial with a layered stack 55, it may be functionally replaced by a single electrode layer. Such a configuration would also be highly suitable for the electronic component package 9 according to various embodiments of the present invention.

As is schematically shown in FIG. 6B, the electrically insulating encapsulation material 57 embeds the MIM arrangement 43.

FIG. 7 is an enlarged partial illustration of an example configuration of the MIM energy storage component 17c in FIGS. 6A-B. As is schematically shown in FIG. 7, each of the electrically conductive vertical nanostructures 51 extends from a first end 57 in electrically conductive contact with the bottom electrode 49 to a top end 59. In particular, the electrically conductive vertical nanostructures 51 may advantageously be grown from the bottom electrode 49, which may in turn be provided on a substrate 50. The substrate 50 may be thinned or, optionally, removed. As is best seen in the enlarged portion of FIG. 7, the bottom conduction-controlling layer 53 conformally coats the nanostructures 51. In the example configuration of FIG. 7, the bottom conduction-controlling layer 53 additionally conformally coats the portions of the bottom electrode 49 that are not covered by the nanostructures 51.

With continued reference to the enlarged portion of FIG. 7, the layered stack 55 of alternating conduction-controlling layers and electrode layers coats the bottom conduction-controlling layer 53 and includes at least a first odd-numbered (first) electrode layer 61 at a bottom of the layered stack 55, a first odd-numbered (first) conduction-controlling layer 63 directly on the first odd-numbered electrode layer 61, and a first even-numbered (second) electrode layer 65 directly on the first odd-numbered conduction-controlling layer 63. In the example configuration of FIG. 7, the layered stack 55 additionally includes a first even-numbered (second) conduction-controlling layer 67, and a second odd-numbered (third) electrode layer 69. Although not shown in FIG. 7, each even-numbered electrode layer (the second electrode layer 65) in the layered stack 55 is electrically conductively connected to the bottom electrode 49, and each odd-numbered electrode layer (the first electrode layer 61 and the third electrode layer 69) in the layered stack 55 is electrically conductively connected to any other odd-numbered electrode layer in the layered stack (to each other).

In embodiments where the MIM energy storage component 17c is a capacitor component, each conduction-controlling layer is made of solid dielectric.

In the example configuration of FIG. 7, the topmost electrode layer (in this case the third electrode layer 69 completely fills a space between adjacent nanostructures 51 more than halfway between the first end 57 and the second end 59 of the nanostructures 51. In the exemplary configuration in FIG. 7, the topmost electrode layer 69 completely fills the space between adjacent nanostructures 51, all the way from the first end 57 to the second end 59, and beyond.

Although not shown in FIG. 7, it should be understood that any layer in the layered stack may be formed by sublayers. In particular the topmost electrode layer 69 may comprise a first sublayer conformally coating the directly underlying conduction-controlling layer 67, and a second sublayer filling up the space between the nanostructures 51.

Moreover, additional sub layer(s) for example as metal diffusion barrier not shown in the figure may conveniently be present in accordance with the present invention disclosure.

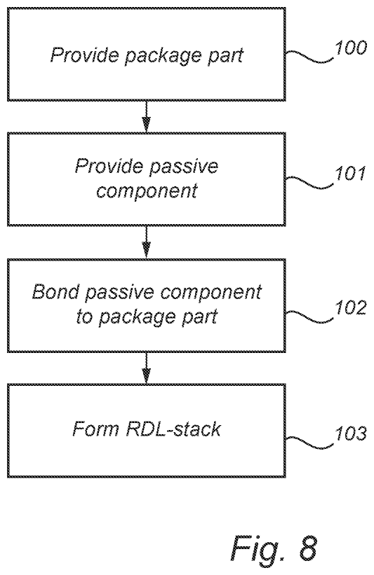

FIG. 8 is a flow-chart schematically illustrating a method according to an example embodiment of the present invention, for manufacturing an electronic component package according to embodiments of the invention. In a first step 100, a package part 19 is provided. As was mentioned above, the package part 19 may comprise a semiconductor circuit and/or an interposer. The package part 19 has a first surface 25 including a plurality of contact pads 23a-d.

A passive component 17c is provided in step 101. The passive component 17c has a first surface 27 including contact pads 31a-c, a second surface 29 substantially parallel to the first surface 27 and spaced apart from the first surface 27, and a side surface connecting the first surface 27 and the second surface 29.

In the subsequent step 102, the contact pads 31a-b on the first surface 27 of the passive component 17c are bonded to a first set 23a of contact pads in the plurality of contact pads on the first surface 25 of the package part 19. This bonding may be carried out in such a way that covalent bonds are formed between the respective contact pads, as was described further above.

Thereafter, in step 103, an RDL stack 21 is formed on a portion of the first surface 25 of the package part 19 and on the second surface 29 of the passive component 17c, embedding the passive component 17c. The RDL stack comprises at least a bottom conductor pattern 33a bonded to a second set of contact pads 23b-d in the plurality of contact pads on the first surface of the package part 19, a top conductor pattern 33d defining a plurality of connecting structures 15 for external connection of the electronic component package 9, and at least one dielectric layer 35a-c arranged between the bottom conductor pattern 33a and the top conductor pattern 33d and comprising vias 37a-c for conductively connecting the bottom conductor pattern 33a with the top conducting pattern 33d.

The person skilled in the art realizes that the present invention by no means is limited to the preferred embodiments described above. On the contrary, many modifications and variations are possible within the scope of the appended claims.

In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. Any reference signs in the claims should not be construed as limiting the scope.

1. An electronic component package, comprising:
a package part comprising a plurality of contact pads on a first surface of the package part;
a component having a first surface including contact pads bonded to a first set of contact pads in the plurality of contact pads on the first surface of the package part, and a second surface spaced apart from the first surface;
a plurality of connecting structures for external electrical connection of the electronic component package; and
an RDL stack interconnecting a second set of contact pads in the plurality of contact pads on the first surface of the package part with the connecting structures for external electrical connection, the RDL stack comprising:
a first conductor layer arranged between the first surface of the package part and a plane including the second surface of the component;
a second conductor layer arranged between the first conductor layer and the plane including the second surface of the component; and
a dielectric layer arranged between the first conductor layer and the second conductor layer and comprising vias for conductively connecting the first conductor layer and the second conductor layer.

2. The electronic component package according to claim 1, wherein the RDL stack embeds the component, including the second surface of the component.

3. The electronic component package according to claim 2, wherein the RDL stack further comprises a third conductor layer at least partly covering the second surface of the component.

4. The electronic component package according to claim 3, wherein the component is at least partly covered by at least one connecting structure in the plurality of connecting structures for external electrical connection of the electronic component package.

5. The electronic component package according to claim 4, wherein the third conductor layer is directly connected to at least a subset of the connecting structures for external electrical connection of the electronic component package.

6. The electronic component package according to claim 1, wherein:
each contact pad in the first set of the plurality of contact pads on the first surface of the package part is surrounded by an oxide layer;
each contact pad on the first surface of the component is surrounded by an oxide layer; and
the oxide layer on the first surface of the package part is bonded to the oxide layer on the first surface of the component by covalent bonds.

7. The electronic component package according to claim 1, wherein the component is a capacitor component.

8. The electronic component package according to claim 7, wherein the capacitor component is a discrete nano-structure based capacitor, comprising:
at least a first plurality of electrically conductive nanostructures;
a dielectric material embedding each nanostructure in the first plurality of conductive nano structures;
a first electrode conductively connected to each nanostructure in the first plurality of nano structures;
a second electrode separated from each nanostructure in the first plurality of nanostructures by the dielectric material, wherein:
a first contact pad on the first surface of the capacitor component is conductively connected to the first electrode; and
a second contact pad on the first surface of the capacitor component is conductively connected to the second electrode.

9. The electronic component package according to claim 8, wherein:
the first electrode is a first electrode layer; and
each nanostructure in the first plurality of nanostructures is vertically arranged on the first electrode layer.

10. The electronic component package according to claim 9, wherein each nanostructure in the first plurality of nanostructures is grown vertically from the first electrode layer

11. The electronic component package according to claim 8, wherein the dielectric material embedding each nanostructure in the first plurality of nanostructures is arranged as a conformal coating on each nanostructure in the first plurality of conductive nanostructures.

12. The electronic component package according to claim 8, wherein the second electrode covers the dielectric material embedding each nanostructure in the first plurality of nanostructures.

13. The electronic component package according to claim 1, wherein the package part includes a semiconductor circuit.

14. The electronic component package according to claim 13, wherein:
the first surface of the package part is constituted by a first surface of the semiconductor circuit.

15. The electronic component package according to claim 1, wherein the package part includes an interposer.

16. The electronic component package according to claim 15, wherein:
the first surface of the package part is constituted by a first surface of the interposer.

17. An electronic device comprising:
a circuit board; and
the electronic component package according to claim 1 connected to the circuit board using the plurality of connecting structures for external electrical connection of the electronic component package.

18. The electronic device according to claim 17, wherein the electronic device is one of an application processor system-in-package; a mobile phone; an entertainment unit; a navigation device; a communications device; a fixed location data unit; a mobile location data unit; a global positioning system (GPS) device; a smart watch; a wearable computing device; a tablet; a server; a computer; a portable computer; a mobile computing device; a battery charger; a USB device; a desktop computer; a personal digital assistant (PDA); a monitor; a computer monitor; a television; a tuner; a radio; a satellite radio; a music player; a digital music player; a portable music player; a digital video player; an automobile; an electric vehicle; a vehicle component; avionics systems; a drone; and a multicopter.

19. A method of manufacturing an electronic component package, comprising the steps of:
providing a package part having a first surface including a plurality of contact pads;
providing a component having a first surface including contact pads, a second surface substantially parallel to the first surface and spaced apart from the first surface, and a side surface connecting the first surface and the second surface;
bonding the contact pads on the first surface of the component to a first set of contact pads in the plurality of contact pads on the first surface of the package part;
forming, on a portion of the first surface of the package part and on the second surface of the component, an RDL stack embedding the component, the RDL stack comprising at least a bottom conductor pattern bonded to a second set of contact pads in the plurality of contact pads on the first surface of the package part, a top conductor pattern defining a plurality of connecting structures for external connection of the electronic component package, and at least one dielectric layer arranged between the bottom conductor pattern and the top conductor pattern and comprising vias for conductively connecting the bottom conductor pattern with the top conducting pattern.
